(19) United States
(12) Patent Application Publication
(10) Pub. No.: US 2026/0282288 A1
(43) Pub. Date: Sep. 17, 2026

(54) SMALL FORM FACTOR TRANSCEIVER MODULE

(71) Applicant: BIZLINK INTERNATIONAL CORP., New Taipei City (TW)

(72) Inventors: Zhaojun XU, New Taipei City (TW); Jinhua MENG, New Taipei City (TW)

(21) Appl. No.: 19/681,196

(22) Filed: May 19, 2026

Related U.S. Application Data
(63) Continuation-in-part of application No. 18/438,509, filed on Feb. 11, 2024, now Pat. No. 12,660,130.

(51) Int. Cl. H05K 7/20

(52) U.S. Cl. CPC H05K 7/20409

(57) ABSTRACT

A small form factor transceiver module includes a base, a printed circuit board, a cover, a heatsink and an adhesive. The printed circuit board has a connecting terminal. The printed circuit board is sandwiched between the base and the cover. The cover has at least one first groove and a mounting surface away from the printed circuit board. The first groove is located on the mounting surface. The adhesive is connected between the mounting surface and the heatsink. The first groove is configured to accommodate an excessive portion of the adhesive.

This application is a Continuation-in-part of U.S. Application Serial Number 18/438,509, filed on February 11, 2024, which is herein incorporated by reference.

### BACKGROUND

### TECHNICAL FIELD

The present disclosure relates to small form factor transceiver modules. More particularly, the present disclosure relates to octal small form-factor pluggable (OSFP) transceiver modules.

### DESCRIPTION OF RELATED ART

In the US patent publication US20180338387A1, an octal small form-factor pluggable (OSFP) transceiver module 226 is disclosed. The OSFP transceiver module 226 includes an upper heat sink 212 and an upper housing member 206. The upper heat sink 212 with fins 214, and cover 216 are integrated with the upper housing member 206, as could be formed by extruding aluminum or other material or building up from separate pieces to an assembly held together by fasteners, bonding, or combination thereof. However, when the upper heat sink 212 and the cover 216 are not formed by aluminum extrusion, it becomes difficult to securely fix the upper heat sink 212 to the cover 216.

### SUMMARY

A technical aspect of the present disclosure is to provide a small form factor transceiver module, which can securely fix the heatsink to the cover by preventing any excessive adhesive from being squeezed out of the space between the cover and the heatsink, thereby maintaining a good appearance of the small form factor transceiver module.

According to an embodiment of the present disclosure, a small form factor transceiver module includes a base, a printed circuit board, a cover, a heatsink and an adhesive. The printed circuit board has a connecting terminal. The printed circuit board is sandwiched between the base and the cover. The cover has at least one first groove and a mounting surface away from the printed circuit board. The first groove is located on the mounting surface. The adhesive is connected between the mounting surface and the heatsink. The first groove is configured to accommodate an excessive portion of the adhesive.

In one or more embodiments of the present disclosure, the first groove extends in a first direction. The cover further has at least one second groove located on the mounting surface. The second groove extends in a second direction intersecting with the first direction. The second groove is configured to accommodate another excessive portion of the adhesive.

In one or more embodiments of the present disclosure, the first groove intersects with the second groove.

In one or more embodiments of the present disclosure, the first groove is separated from the second groove.

In one or more embodiments of the present disclosure, the cover includes a body, two sidewalls and at least one stopper. The mounting surface is located on the body. The sidewalls are connected with the body. The mounting surface is located between the sidewalls. The sidewalls are configured to abut against the heatsink. The stopper is disposed on the mounting surface and located between the sidewalls. The stopper is configured to abut against the heatsink.

In one or more embodiments of the present disclosure, the stopper is separated from the sidewalls.

In one or more embodiments of the present disclosure, the stopper is connected with at least one of the sidewalls.

In one or more embodiments of the present disclosure, a quantity of the stopper is two. The first groove and the second groove are located between the stoppers.

In one or more embodiments of the present disclosure, the heatsink includes a bottom plate, a top plate and a plurality of fins. The adhesive is connected between the mounting surface and the bottom plate. The fins are separated from each other and connected between the bottom plate and the top plate. A width of the top plate is greater than a width of the bottom plate. Both of the top plate and the bottom plate are separated from both of the sidewalls.

In one or more embodiments of the present disclosure, the bottom plate of the heatsink is separated from both of the sidewalls by a plurality of side protrusions connecting to inner sides of the sidewalls.

In one or more embodiments of the present disclosure, the bottom plate has a first thickness. The stopper has a second thickness. The first thickness is equal to or larger than the second thickness.

According to an embodiment of the present disclosure, a small form factor transceiver module includes a base, a printed circuit board, a cover, a heatsink and an adhesive. The printed circuit board has a connecting terminal. The printed circuit board is sandwiched between the base and the cover. The cover has a mesh of grooves and a mounting surface away from the printed circuit board. The grooves are located on the mounting surface. The adhesive is connected between the mounting surface and the heatsink. The grooves are configured to accommodate an excessive portion of the adhesive.

In one or more embodiments of the present disclosure, the cover includes a body, two sidewalls and two stoppers. The mounting surface is located on the body. The sidewalls are connected with the body. The stoppers are disposed on the mounting surface forming an enclosure around the mounting surface with the sidewalls. A width of the top plate is greater than a width of the bottom plate. Both of the top plate and the bottom plate are separated from both of the sidewalls.

In one or more embodiments of the present disclosure, at least one of the stoppers is separated from the sidewalls.

In one or more embodiments of the present disclosure, at least one of the stoppers is connected with one of the sidewalls.

In one or more embodiments of the present disclosure, the heatsink includes a bottom plate, a top plate and a plurality of fins. The adhesive is connected between the mounting surface and the bottom plate. The fins are separated from each other and connected between the bottom plate and the top plate. The bottom plate, the top plate and the fins are one piece formed. A width of the top plate is greater than a width of the bottom plate. Both of the top plate and the bottom plate are separated from both of the sidewalls by a plurality of side protrusions connecting to inner sides of the sidewalls.

In one or more embodiments of the present disclosure, the bottom plate has a first thickness. The stopper has a second thickness. The first thickness is equal to or larger than the second thickness.

In one or more embodiments of the present disclosure, the connecting terminal points to an installing direction. The small form factor transceiver module further includes a latch. The latch is connected with an end of the base opposite to the installing direction.

In one or more embodiments of the present disclosure, the grooves are arranged in a pattern of grids.

According to an embodiment of the present disclosure, a small form factor transceiver module includes a cover and a heatsink. The cover has a mounting surface and a first groove recessed from the mounting surface. The first groove has a bottom surface. The heatsink is disposed on the mounting surface and has a lower surface facing the mounting surface. The lower surface of the heatsink and the bottom surface of the first groove have a first distance therebetween.

According to an embodiment of the present disclosure, a small form factor transceiver module includes a cover, a heatsink, and an adhesive. The cover has a mounting surface. The heatsink is disposed on the mounting surface and has a lower surface facing the mounting surface. The adhesive is connected between the mounting surface of the cover and the lower surface of the heatsink.

According to an embodiment of the present disclosure, a small form factor transceiver module includes a cover, a heatsink, and a base. The cover has a first side and a second side opposite to each other. The heatsink is disposed on the first side of the cover. The base is disposed on the second side of the cover. The cover has a screw hole penetrating the cover and connecting the first side and the second side.

The above-mentioned embodiments of the present disclosure have at least the following advantage: when too much of the adhesive is used between the cover and the heatsink, an excessive portion of the adhesive will be accommodated within the first groove and the second groove. This means the excessive portion of the adhesive can be prevented from being squeezed out of the space between the cover and the heatsink. Therefore, the small form factor transceiver module can maintain a good appearance.

### BRIEF DESCRIPTION OF THE DRAWINGS

The disclosure can be more fully understood by reading the following detailed description of the embodiments, with reference made to the accompanying drawings as follows:

FIG. 1 is a schematic view of a small form factor transceiver module according to an embodiment of the present disclosure;

FIG. 2 is an exploded view of the small form factor transceiver module of FIG. 1;

FIG. 3 is a top view of the cover of FIG. 1;

FIG. 4 is a sectional view along the sectional line A-A of FIG. 3;

FIG. 5 is a sectional view along the sectional line B-B of FIG. 3;

FIG. 6 is a front view of the heatsink of FIG. 1;

FIG. 7A is an enlarged view of zone M of FIG. 1;

FIG. 7B is an enlarged view of the structure in FIG. 7A;

FIG. 8 is a partially enlarged top view of a cover according to another embodiment of the present disclosure;

FIG. 9 is a partially enlarged top view of a cover according to a further embodiment of the present disclosure;

FIG. 10 is a schematic view of a small form factor transceiver module according to another embodiment of the present disclosure;

FIG. 11 is an exploded view of the small form factor transceiver module of FIG. 10;

FIG. 12 is a top view of the cover of FIG. 11;

FIG. 13 is a partial sectional view of the cover with the heatsink disposed thereon along the line C-C of FIG. 12;

FIG. 14 is a partial sectional view of the cover along the line D-D of FIG. 12;

FIG. 15 is a partial sectional view of the cover along the line E-E of FIG. 12; and

FIG. 16 is a partially enlarged view of the cover and the heatsink of FIG. 10.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

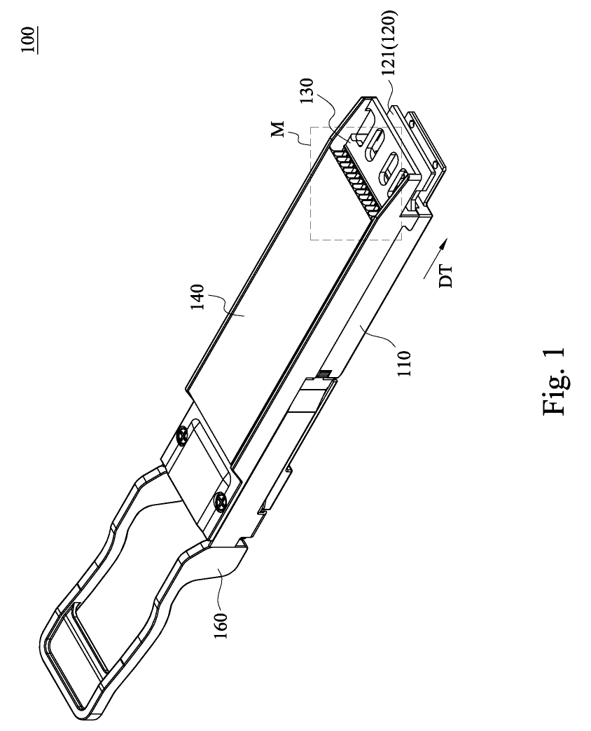

FIGS. 1-8 are drawn according to the actual scale. For the sake of concise description in this specification, the scales of the elements are not listed one by one. However, the scale and position of each element should be regarded as part of the scope of this specification.

Furthermore, if the description in this specification is insufficient to explain the detailed design of the elements and makes it uneasy to implement, please take the octal small form-factor pluggable (OSFP) transceiver module disclosed in the US Patent publication US20180338387A1as a reference.

As shown in FIGS. 1-8, a small form factor transceiver module 100 is provided in the present disclosure. Moreover, for example, the small form factor transceiver module 100 is applied to connect a network device, such as a switch, to fiber or copper cable.

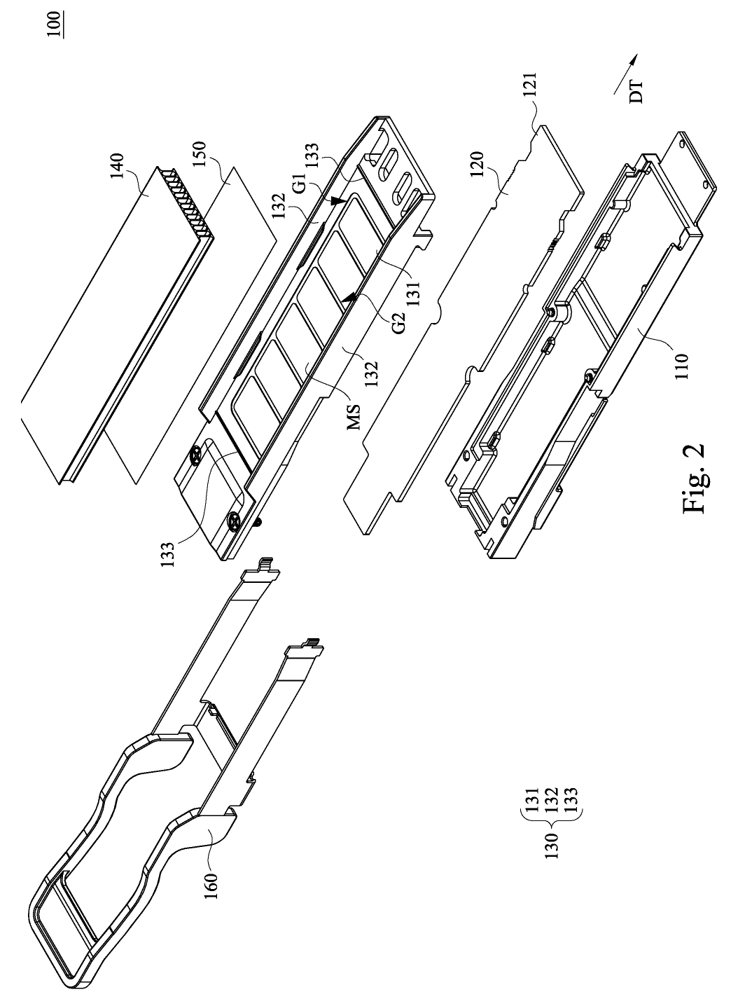

FIG. 1 is a schematic view of a small form factor transceiver module 100 according to an embodiment of the present disclosure. FIG. 2 is an exploded view of the small form factor transceiver module 100 of FIG. 1. In this embodiment, as shown in FIGS. 1-2, the small form factor transceiver module 100 includes a base 110, a printed circuit board 120, a cover 130, a heatsink 140, an adhesive 150 and a latch 160. When applied, the adhesive 150 is in a liquid form. For an easy understanding of the internal structure of the small form factor transceiver module 100, the adhesive 150 is presented as a layer in FIG. 2.

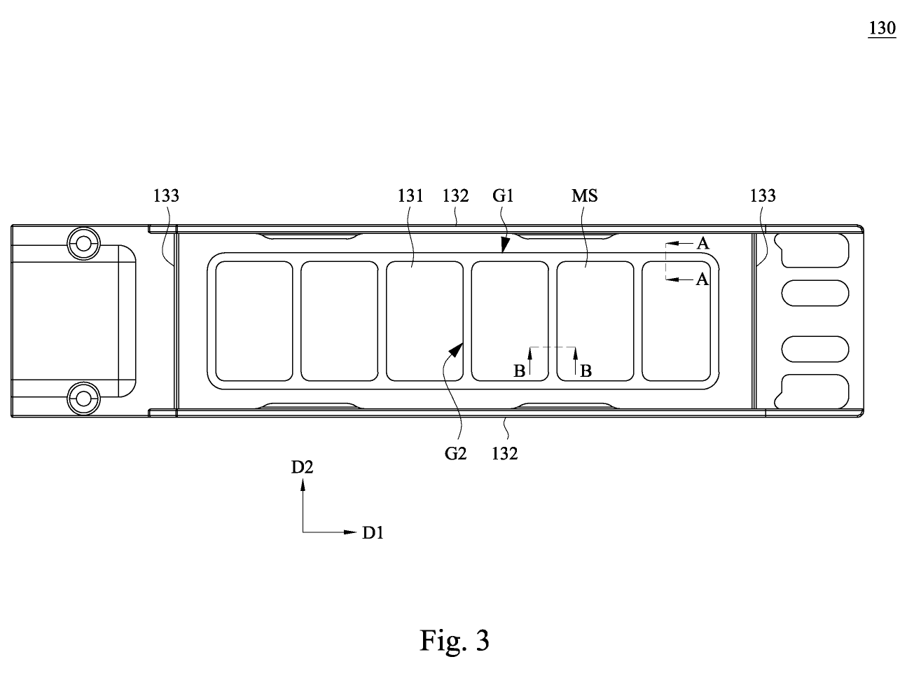

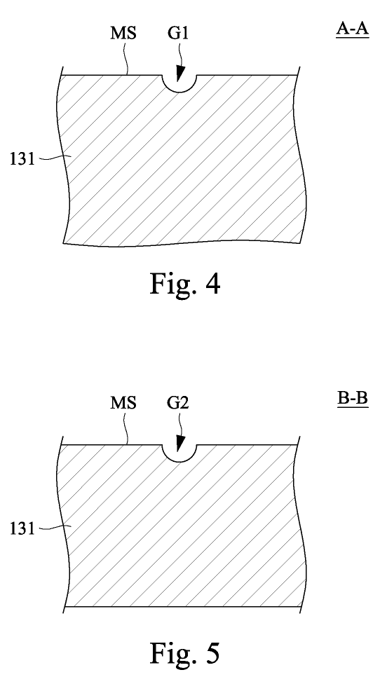

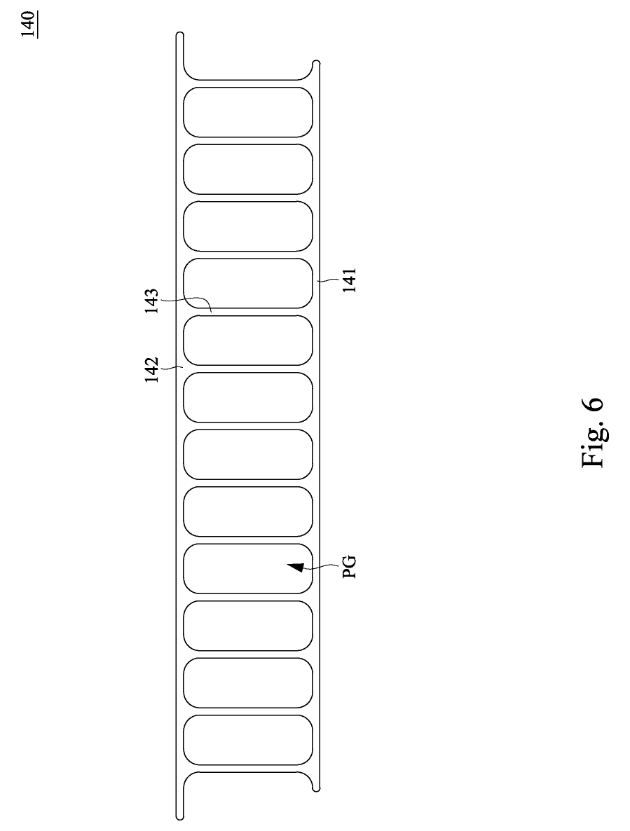

FIG. 3 is a top view of the cover 130 of FIG. 1. FIG. 4 is a sectional view along the sectional line A-A of FIG. 3. FIG. 5 is a sectional view along the sectional line B-B of FIG. 3. As shown in FIGS. 2-5, the cover 130 includes a body 131, two sidewalls 132 and at least one stopper 133. The sidewalls 132 are connected with the body 131. Moreover, the cover 130 has at least one first groove G1, at least one second groove G2 and a mounting surface MS. For example, as shown in FIGS. 3-4, a quantity of the first groove G1 is plural while a quantity of the second groove G2 is also plural. The mounting surface MS is located on the body 131 and between the sidewalls 132. Moreover, as shown in FIGS. 3-4, a quantity of the stopper 133 is two. The stoppers 133 are disposed on the mounting surface MS and located between the sidewalls 132 to form with the sidewalls 132 an enclosure around the mounting surface MS. At least one of the stoppers 133 is connected with at least one of the sidewalls 132. The first grooves G1 and the second grooves G2 are located on the mounting surface MS and between the stoppers 133. Each of the first grooves G1 extends in a first direction D1. Each of the second grooves G2 extends in a second direction D2 intersecting with the first direction D1. For example, the second direction D2 is perpendicular to the first direction D1. In this embodiment, each of the first grooves G1 intersects with at least one of the second grooves G2, such that the first grooves G1 and the second grooves G2 are arranged in a pattern of grids. In other words, the cover 130 has a mesh of grooves (i.e., the first grooves G1 and the second grooves G2) located on the mounting surface MS.

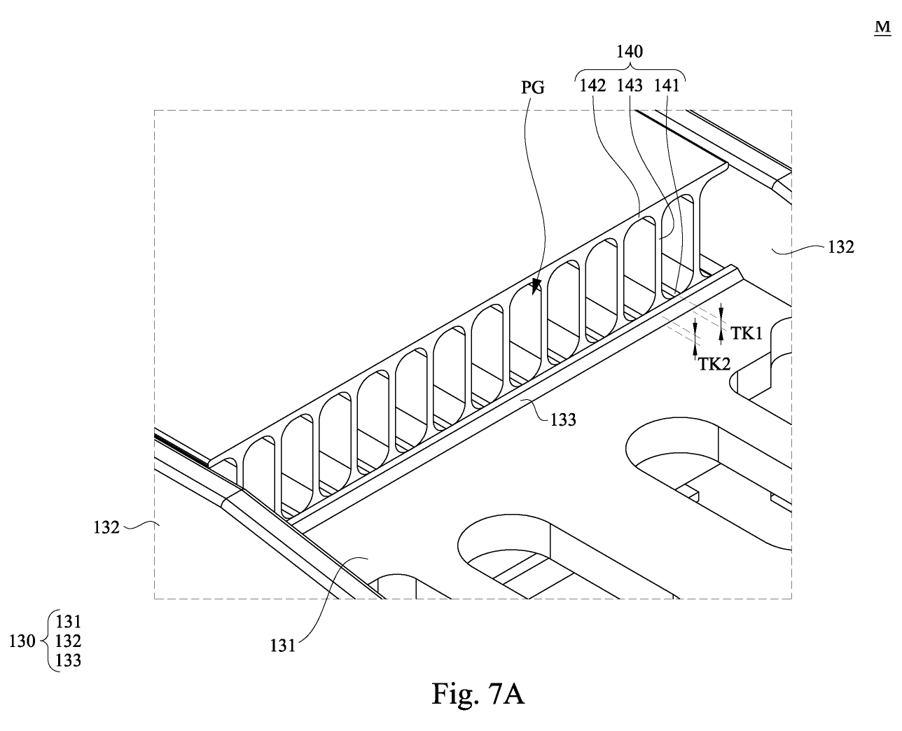

FIG. 6 is a front view of the heatsink 140 of FIG. 1. In this embodiment, as shown in FIG. 6, the heatsink 140 includes a bottom plate 141, a top plate 142 and a plurality of fins 143. The fins 143 are separated from each other and connected between the bottom plate 141 and the top plate 142. Adjacent two of the fins 143 define a passage PG therebetween to allow air to flow through for heat dissipation. In practice, the bottom plate 141, the top plate 142 and the fins 143 are one piece formed. It is worth to note that, in this embodiment, a quantity of the fins 143 is between 12 and 14 inclusively, such that a larger amount of surface area is provided by the fins 143 while a size of each of the passages PG can be maintained in an appropriate magnitude, leading to a better effect of heat dissipation. As shown in FIG. 6, for example, the quantity of the fins 143 is 13. In addition, a width of the top plate 142 is greater than a width of the bottom plate 141.

As shown in FIGS. 1-2, the printed circuit board 120 has a connecting terminal 121. The connecting terminal 121 points to an installing direction DT and is configured to electrically connect with a network device (not shown), for example. The latch 160 is connected with an end of the base 110 opposite to the installing direction DT. The printed circuit board 120 is sandwiched between the base 110 and the cover 130. The mounting surface MS is located on a side of the cover 130 away from the printed circuit board 120. The adhesive 150 is connected between the mounting surface MS and the heatsink 140 in order to stick together the mounting surface MS and the heatsink 140. To be more specific, the adhesive 150 is connected between the mounting surface MS of the cover 130 and the bottom plate 141 (please see FIG. 6 for the bottom plate 141) of the heatsink 140. The sidewalls 132 and the stoppers 133 are configured to abut against the heatsink 140. In other words, the sidewalls 132 and the stoppers 133 are configured to restrict the position of the heatsink 140.

It is worth to note that, in this embodiment, the first grooves G1 and the second grooves G2 are configured to accommodate an excessive portion of the adhesive 150. In practice, when too much of the adhesive 150 is used between the cover 130 and the heatsink 140, an excessive portion of the adhesive 150 will be accommodated within the first grooves G1 and the second grooves G2. This means the excessive portion of the adhesive 150 can be prevented from being squeezed out of the space between the cover 130 and the heatsink 140. Therefore, the small form factor transceiver module 100 can maintain a good appearance.

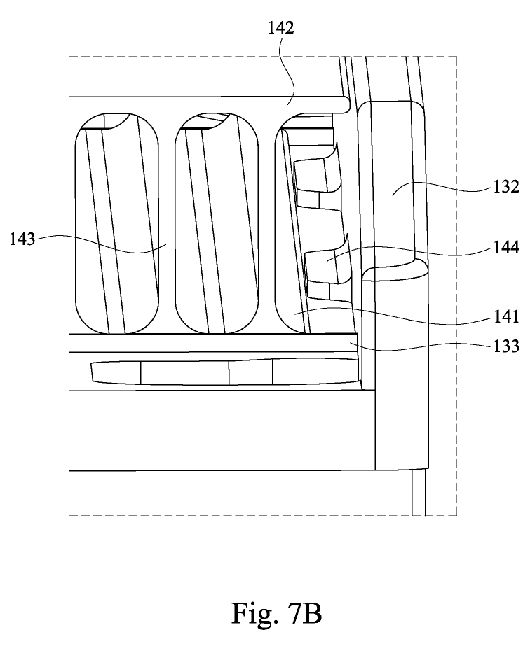

FIG. 7A is an enlarged view of zone M of FIG. 1. FIG. 7B is an enlarged view of the structure in FIG. 7A. As shown in FIGS. 7A and 7B, the bottom plate 141 has a first thickness TK1. The stopper 133 has a second thickness TK2. In this embodiment, the first thickness TK1 of the bottom plate 141 of the heatsink 140 is equal to or larger than the second thickness TK2 of the stopper 133. In this way, the passages PG defined by the fins 143 will be free from blockage by the stopper 133. Thus, the air flowing through the passages PG will not be affected by the stopper 133. For example, as shown in FIG. 7A, the first thickness TK1 of the bottom plate 141 of the heatsink 140 is equal to the second thickness TK2 of the stopper 133. In addition, as shown in FIG. 7B, both of the top plate 142 and the bottom plate 141 are separated from both of the sidewalls 132. Specifically, the heatsink 140 further includes a plurality of side protrusions 144. The side protrusions 144 are connected to inner sides of the sidewalls 132. The bottom plate 141 of the heatsink 140 is separated from both of the sidewalls 132 by the side protrusions 144.

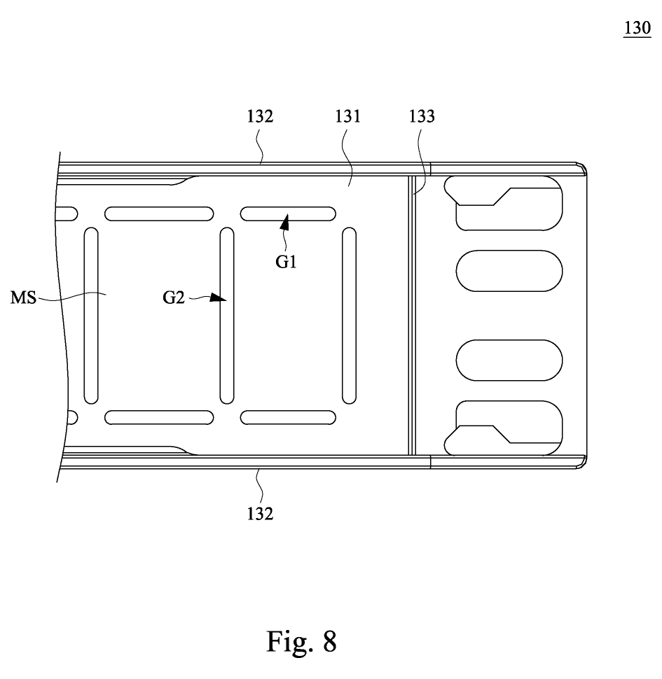

FIG. 8 is a partially enlarged top view of a cover 130 according to another embodiment of the present disclosure. In this embodiment, as shown in FIG. 8, each of the first grooves G1 is separated from the second grooves G2, according to the actual situation.

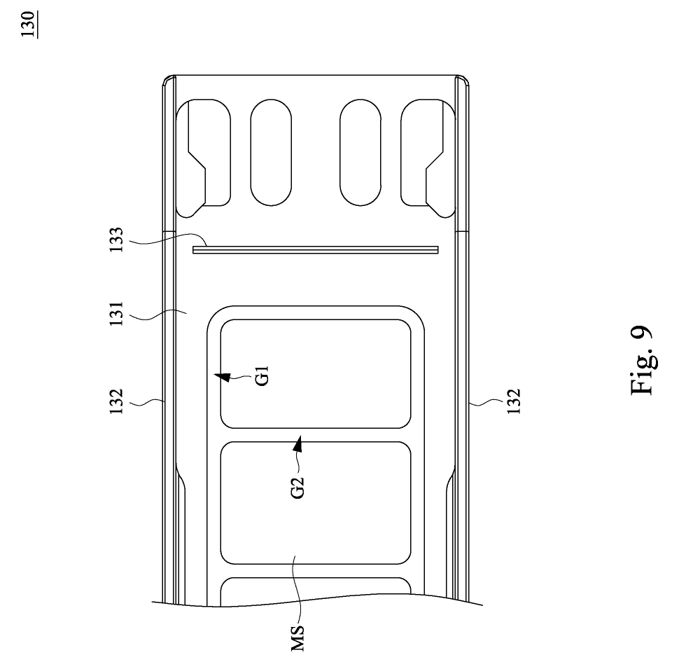

FIG. 9 is a partially enlarged top view of a cover 130 according to a further embodiment of the present disclosure. In this embodiment, as shown in FIG. 9, at least one of the stoppers 133 is separated from the sidewalls 132, according to the actual situation.

In conclusion, the aforementioned embodiments of the present disclosure have at least the following advantage: when too much of the adhesive is used between the cover and the heatsink, an excessive portion of the adhesive will be accommodated within the first grooves and the second grooves. This means the excessive portion of the adhesive can be prevented from being squeezed out of the space between the cover and the heatsink. Therefore, the small form factor transceiver module can maintain a good appearance.

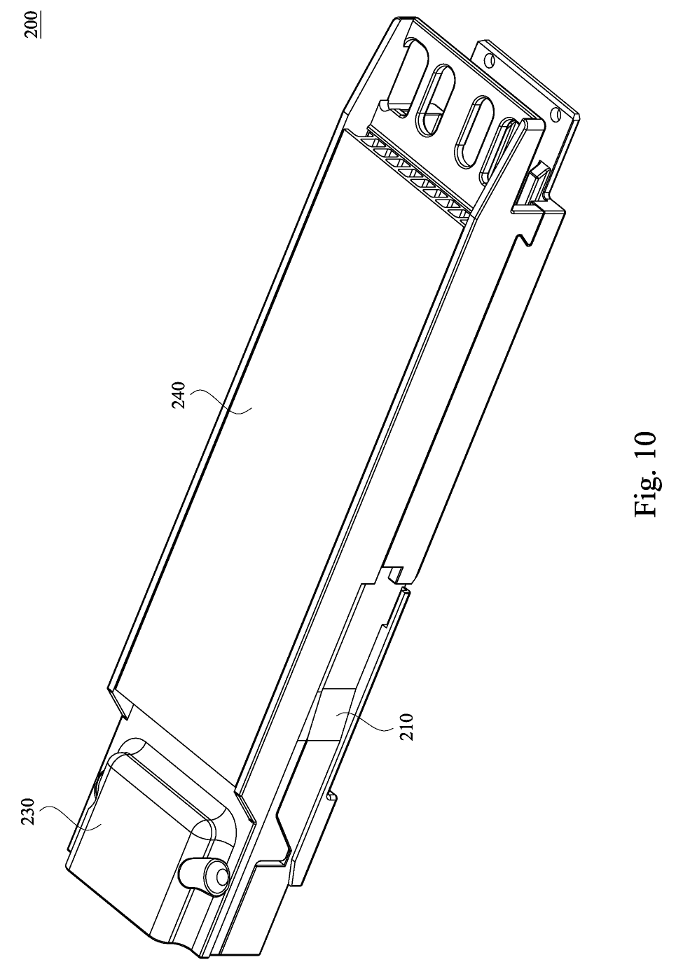

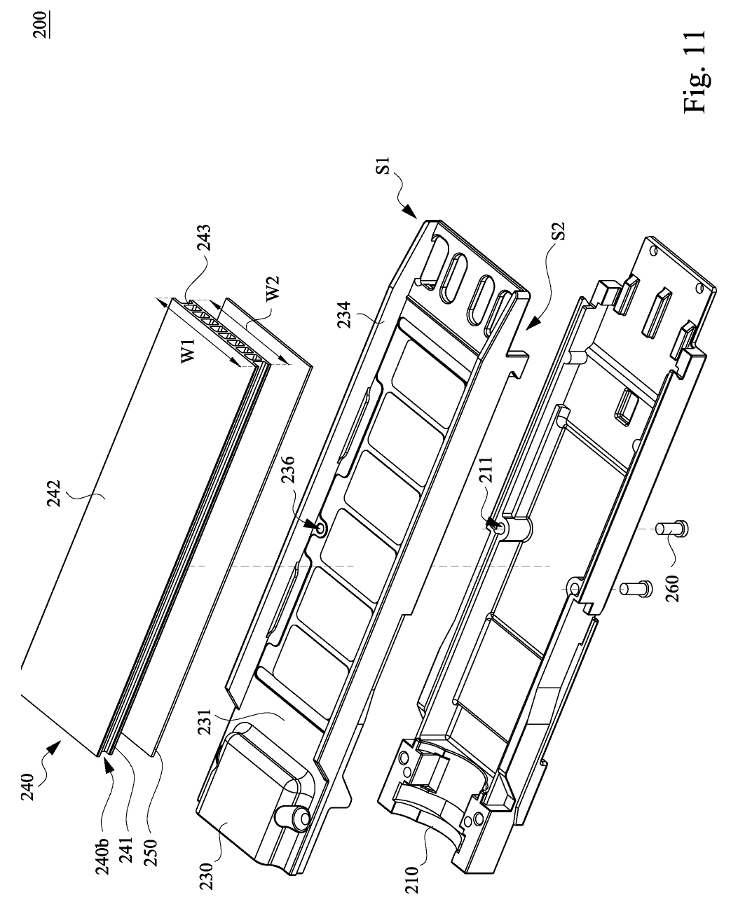

FIGS. 10-16 illustrate a small form factor transceiver module 200 according to another embodiment of the present disclosure, which introduces structural enhancements to further improve the manufacturing yield and soldering quality. FIG. 10 is a schematic view of the small form factor transceiver module 200 according to another embodiment of the present disclosure. FIG. 11 is an exploded view of the small form factor transceiver module 200 of FIG. 10. In this embodiment, as shown in FIGS. 10 and 11, the small form factor transceiver module 200 includes a base 210, a cover 230, a heatsink 240, an adhesive 250, and a screw 260.

The cover 230 has a first side S1 and a second side S2 opposite to each other. The heatsink 240 is disposed on the first side S1 of the cover 230, and the base 210 is disposed on the second side S2 of the cover 230. The adhesive 250 is connected between the cover 230 and the heatsink 240 to firmly bond the components. In one or more embodiments, the adhesive 250 includes a lead-free solder paste, such as a solder paste having a flux. For instance, an Sn42Bi58 alloy can be utilized. Utilizing the solder paste having a flux ensures robust fixation and excellent thermal conduction after the reflow heating process, while meeting environmental compliance and eliminating the need for subsequent wipe-cleaning processes for any overflowing paste.

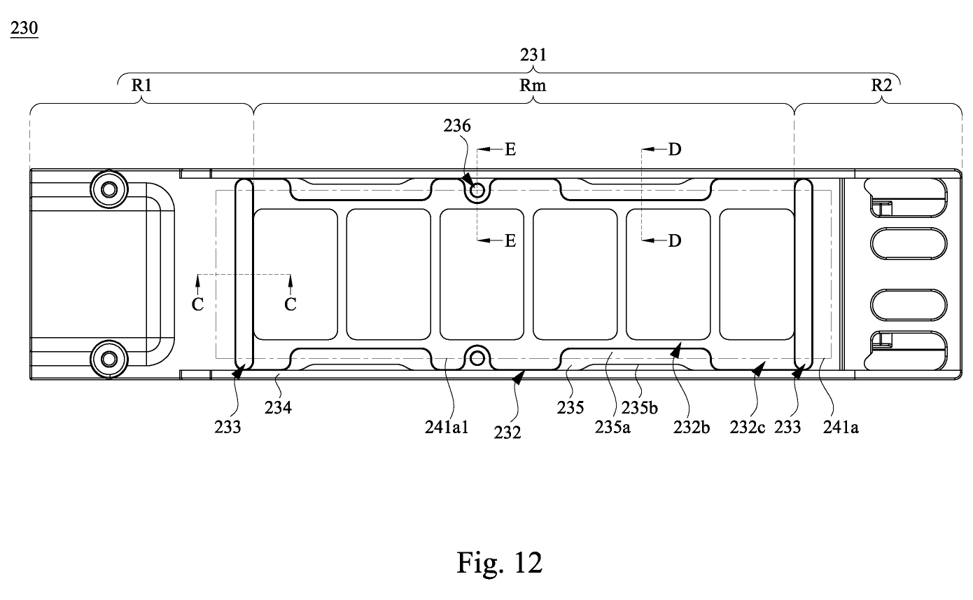

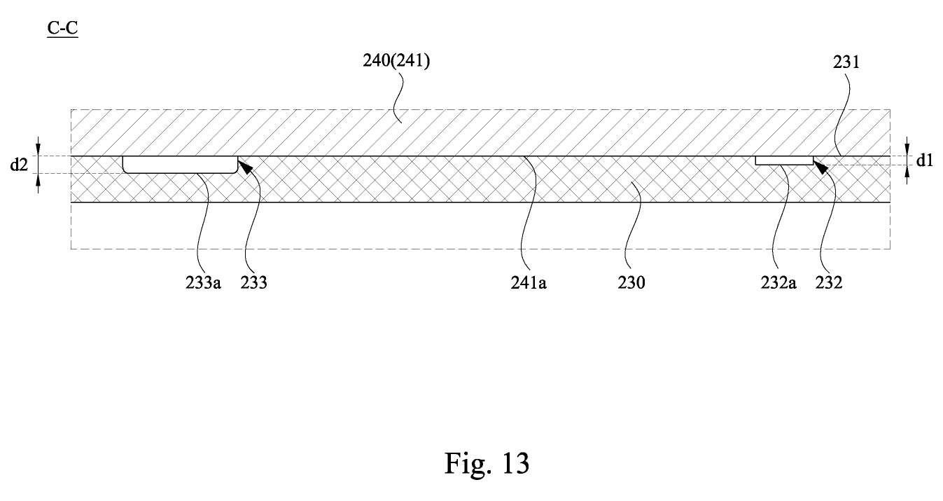

FIG. 12 is a top view of the cover 230 of FIG. 11. FIG. 13 is a partial sectional view of the cover 230 with the heatsink 240 disposed thereon along the line C-C of FIG. 12. As shown in FIGS. 12 and 13, the cover 230 has a mounting surface 231. The adhesive 250 is connected between the mounting surface 231 of the cover 230 and a lower surface 241a of the heatsink 240. The mounting surface 231 has two end regions R1, R2 and a middle region Rm between the two end regions R1, R2. To optimize the distribution of the adhesive 250, the cover 230 has a first groove 232 recessed from the mounting surface 231 and located in the middle region Rm. Furthermore, the cover 230 has two second grooves 233 recessed from the mounting surface 231 and respectively located in the two end regions R1, R2. In one or more embodiments, the first groove 232 intersects with the second grooves 233.

As shown in FIG. 13, the first groove 232 has a bottom surface 232a, and each of the second grooves 233 has a bottom surface 233a. When the heatsink 240 is disposed on the mounting surface 231, the lower surface 241a of the heatsink 240 and the bottom surface 232a of the first groove 232 have a first distance d1 therebetween. Similarly, the lower surface 241a and the bottom surface 233a of the corresponding second groove 233 have a second distance d2 therebetween. Notably, the first distance d1 is different from the second distance d2. Specifically, the second grooves 233 are configured to be deeper than the first groove 232. In practice, this non-uniform depth arrangement enables the second grooves 233 to efficiently accommodate an excessive portion of the adhesive 250 (including the flux). This prevents the excessive adhesive 250 from overflowing out of the boundaries of the cover 230, thereby eliminating the need for manual wiping operations, significantly enhancing the production capacity, and maintaining a clean external appearance.

As shown in FIG. 12, the first groove 232 has a narrower portion 232b and a wider portion 232c connected to each other. The narrower portion 232b is entirely covered by the lower surface 241a (represented by a dashed box in FIG. 12) of the heatsink 240, while the wider portion 232c extends beyond an edge 241a1 of the lower surface 241a. During the reflow heating process of the adhesive 250, the flux within the adhesive 250 vaporizes and generates internal gases. The structural design of the wider portion 232c extending beyond the edge 241a1 of the lower surface 241a acts as an exhaust channel, allowing the expanding gases to properly escape rather than forming internal bubbles. This effectively ensures the structural integrity and optimal thermal performance of the bonded interface.

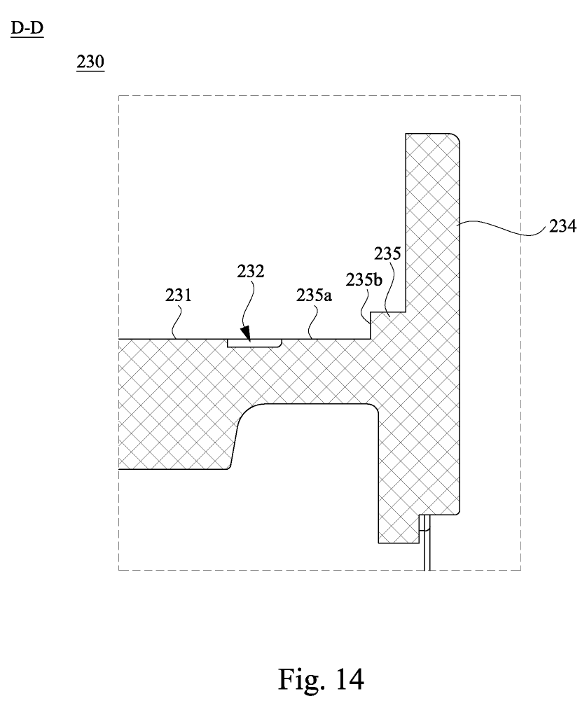

FIG. 14 is a partial sectional view of the cover 230 along the line D-D of FIG. 12. As shown in FIGS. 12 and 14, the cover 230 includes a stepped structure 235 adjacent to the first groove 232. In some embodiments, the stepped structure 235 may include a plurality of steps to accommodate and support the structural variations of the heatsink 240. The stepped structure 235 has a supporting surface 235a and an abutting surface 235b. As shown in FIGS. 12 and 14 with reference to FIG. 13, the lower surface 241a of the heatsink 240 is securely supported on the supporting surface 235a, and the abutting surface 235b is configured to abut against a lateral side 240b (please see FIG. 11) of the heatsink 240, thereby ensuring precise positioning of the heatsink 240 on the cover 230.

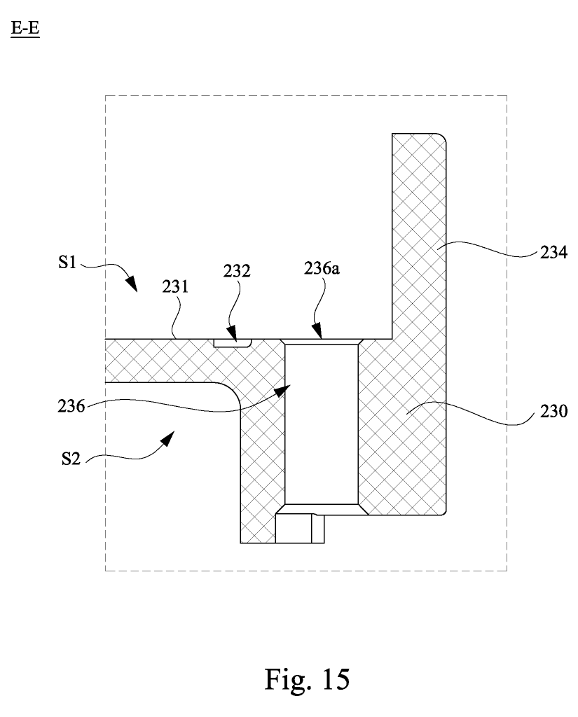

FIG. 15 is a partial sectional view of the cover 230 along the line E-E of FIG. 12. As shown in FIGS. 11, 12, and 15, the cover 230 has a screw hole 236 penetrating the cover 230 and connecting the first side S1 and the second side S2. The screw hole 236 has an opening 236a on the mounting surface 231. In one or more embodiments, the adhesive 250 is located around the screw hole 236. Furthermore, the heatsink 240 covers the opening 236a of the screw hole 236 and the at least one groove (such as the first groove 232 and/or the second grooves 233). The base 210 has a through hole 211 (please see FIG. 11), and the screw 260 passes through the through hole 211 from a side of the base 210 away from the cover 230 and is screwed into the screw hole 236 to mechanically fasten the base 210 to the cover 230. By adopting the penetrating screw hole 236 instead of a conventional blind hole, the risk of the screw 260 directly piercing or pushing up the material of the cover 230 during an over-tightening or deep-tapping process can be prevented. Consequently, the mounting surface 231 remains flat without any permanent localized protrusions or bulging, which thoroughly resolves the “see-saw” instability when the heatsink 240 is placed, thus guaranteeing high-quality and reliable soldering.

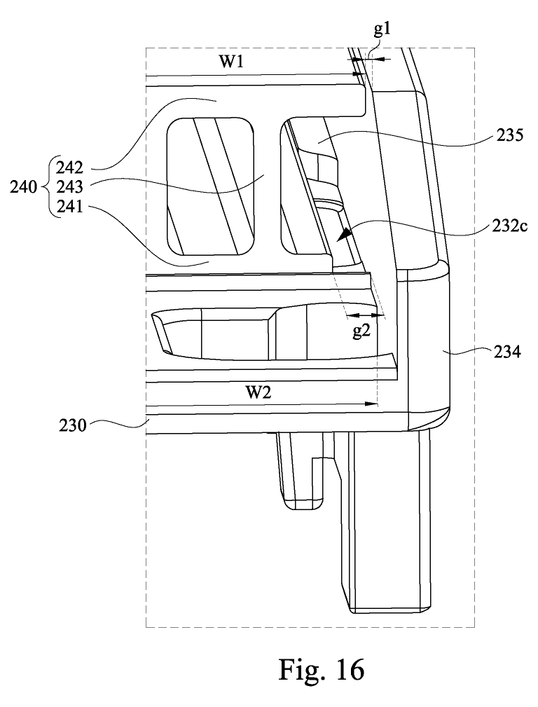

FIG. 16 is a partially enlarged view of the cover 230 and the heatsink 240 of FIG. 10. As shown in FIGS. 11, 13, and 16, the heatsink 240 includes a bottom plate 241 having the lower surface 241a, a top plate 242, and a plurality of fins 243 separated from each other and connected between the bottom plate 241 and the top plate 242. The cover 230 includes two sidewalls 234. A width W1 of the top plate 242 is configured to be greater than a width W2 of the bottom plate 241. Furthermore, a gap g1 between the top plate 242 and one of the two sidewalls 234 is smaller than a gap g2 between the bottom plate 241 and the one of the two sidewalls 234. This geometric configuration elegantly avoids physical interference with the structural features of the cover 230 while maximizing the heat dissipation area provided by the top plate 242.

In conclusion, the aforementioned embodiments as shown in FIGS. 10-16 of the present disclosure have at least the following advantages. First, the structural design of the grooves (e.g., the non-uniform depth arrangement of the first groove and the deeper second groove) efficiently accommodates an excessive portion of the adhesive and the flux. This means the excessive portion of the adhesive can be thoroughly prevented from being squeezed out of the space between the cover and the heatsink, thereby maintaining a good appearance and enhancing production capacity without manual wiping. Second, the wider portion of the first groove extending beyond the edge of the lower surface of the heatsink elegantly serves as an exhaust channel, allowing internal expanding gases generated during a reflow heating process to properly escape, which ensures the structural integrity of the bonded interface. Furthermore, the implementation of the penetrating screw hole prevents the mounting surface of the cover from any permanent deformation or bulging during fastening or tapping processes. Therefore, exceptional flatness of the mounting surface is guaranteed, thoroughly resolving the see-saw instability and ensuring high-quality, reliable soldering for the small form factor transceiver module.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A small form factor transceiver module, comprising:
a cover having a mounting surface and a first groove recessed from the mounting surface, wherein the first groove has a bottom surface; and
a heatsink disposed on the mounting surface and having a lower surface facing the mounting surface, wherein the lower surface of the heatsink and the bottom surface of the first groove have a first distance therebetween.

2. The small form factor transceiver module of claim 1, wherein the cover further has a second groove recessed from the mounting surface, the second groove has a bottom surface, the lower surface of the heatsink and the bottom surface of the second groove have a second distance therebetween, and the first distance is different from the second distance.

3. The small form factor transceiver module of claim 2, wherein the first groove intersects with the second groove.

4. The small form factor transceiver module of claim 2, wherein the mounting surface has two end regions and a middle region between the two end regions, the first groove is located in the middle region, and the second groove is located in one of the two end regions.

5. The small form factor transceiver module of claim 1, wherein the cover comprises a stepped structure adjacent to the first groove, the stepped structure has a supporting surface and an abutting surface, the lower surface of the heatsink is supported on the supporting surface, and the abutting surface is configured to abut against a lateral side of the heatsink.

6. The small form factor transceiver module of claim 1, wherein the first groove has a narrower portion and a wider portion connected to each other.

7. The small form factor transceiver module of claim 6, wherein the narrower portion is covered by the lower surface of the heatsink, and the wider portion extends beyond an edge of the lower surface.

8. A small form factor transceiver module, comprising:
a cover having a mounting surface;
a heatsink disposed on the mounting surface and having a lower surface facing the mounting surface; and
an adhesive connected between the mounting surface of the cover and the lower surface of the heatsink.

9. The small form factor transceiver module of claim 8, wherein the adhesive comprises a lead-free solder paste.

10. The small form factor transceiver module of claim 8, wherein the adhesive is a solder paste having a flux.

11. The small form factor transceiver module of claim 8, wherein the cover has at least one groove recessed from the mounting surface and configured to accommodate an excessive portion of the adhesive.

12. The small form factor transceiver module of claim 11, wherein the at least one groove is partially covered by the lower surface of the heatsink and partially extends beyond an edge of the lower surface.

13. The small form factor transceiver module of claim 11, wherein the mounting surface has two end regions and a middle region between the two end regions, the at least one groove includes a first groove located in the middle region and a second groove located in one of the two end regions, and the second groove is deeper than the first groove.

14. The small form factor transceiver module of claim 8, wherein the cover comprises two sidewalls, the mounting surface is located between the two sidewalls, the heatsink comprises:
a bottom plate having the lower surface;
a top plate; and
a plurality of fins separated from each other and connected between the bottom plate and the top plate,
wherein a gap between the top plate and one of the two sidewalls is smaller than a gap between the bottom plate and the one of the two sidewalls.

15. A small form factor transceiver module, comprising:
a cover having a first side and a second side opposite to each other;
a heatsink disposed on the first side of the cover; and
a base disposed on the second side of the cover,
wherein the cover has a screw hole penetrating the cover and connecting the first side and the second side.

16. The small form factor transceiver module of claim 15, further comprising a screw, wherein the base has a through hole, and the screw passes through the through hole and is screwed into the screw hole to fasten the base to the cover.

17. The small form factor transceiver module of claim 15, wherein the cover has a mounting surface on the first side for the heatsink to be attached thereto, and the screw hole has an opening on the mounting surface.

18. The small form factor transceiver module of claim 17, further comprising an adhesive connected between the mounting surface of the cover and the heatsink, and the adhesive is located around the screw hole.

19. The small form factor transceiver module of claim 18, wherein the cover has at least one groove recessed from the mounting surface and configured to accommodate an excessive portion of the adhesive, and the heatsink covers the opening of the screw hole and the at least one groove.

20. The small form factor transceiver module of claim 15, wherein the heatsink comprises:
a bottom plate adjacent to the cover;
a top plate away from the cover; and
a plurality of fins separated from each other and connected between the bottom plate and the top plate,
wherein a width of the top plate is greater than a width of the bottom plate.
